(19) United States
(12) Patent Application Publication
(10) Pub. No.: US 2026/0208622 A1
(43) Pub. Date: Jul. 23, 2026

(54) INFORMATION PROCESSING SYSTEM, INFORMATION PROCESSING APPARATUS, AND NON-TRANSITORY COMPUTER READABLE MEDIUM

(71) Applicant: TOYOTA JIDOSHA KABUSHIKI KAISHA, Toyota-shi (JP)

(72) Inventors: Yu NAGATA, Chofu-shi (JP); Makoto MATSUSHITA, Ichinomiya-shi (JP); Kei KOSAKA, Meguro-ku (JP); Sho MINAGAWA, Nagoya-shi (JP); Haruka FUTATSUBASHI, Chiyoda-ku (JP); Ryota TATSUMI, Nagoya-shi (JP); Yo OKUMURA, Chofu-shi (JP); Toshifumi MICHIDA, Okazaki-shi (JP)

(73) Assignee: TOYOTA JIDOSHA KABUSHIKI KAISHA, Toyota-shi (JP)

(21) Appl. No.: 19/416,271

(22) Filed: Dec. 11, 2025

(30) Foreign Application Priority Data
Jan. 22, 2025 (JP) 2025-009369

(51) Int. Cl. B60L 58/16; G07C 5/04

(52) U.S. Cl. CPC B60L 58/16; G07C 5/04

(57) ABSTRACT

An information processing apparatus includes a controller that, when a first elapsed time, a first degradation level, and a first actual number of charges of a battery are provided from a vehicle, calculates a first service life of the battery from the first elapsed time and the first degradation level, and calculates a first remaining number of charges of the battery from the first actual number of charges. When the first elapsed time, the first degradation level, and the first actual number of charges are not provided from the vehicle, the controller estimates a second elapsed time of the battery from a total travel distance and a manufacturing date of the vehicle, and estimates a second degradation level and a second actual number of charges of the battery by applying the second elapsed time to predetermined statistical information.

### CROSS-REFERENCE TO RELATED APPLICATION

This application claims priority to Japanese Patent Application No. 2025-009369 filed on Jan. 22, 2025, the entire contents of which are incorporated herein by reference.

### TECHNICAL FIELD

The present disclosure relates to an information processing system, an information processing apparatus, and a non-transitory computer readable medium.

### BACKGROUND

Technology related to estimating the degradation levels of batteries that drive vehicles is known. For example, Patent Literature (PTL) 1 discloses technology that presents appropriate usage methods for batteries in electric vehicles based on the usage statuses of the batteries.

### CITATION LIST

### Patent Literature

PTL 1: JP 7015395 B2

### SUMMARY

However, PTL 1 does not disclose technology for estimating the degradation levels of batteries after 2 to 3 years. Therefore, there is room for improvement in technology related to estimating the degradation levels of batteries that drive vehicles.

It would be helpful to improve technology related to estimating the degradation levels of batteries that drive vehicles.

An information processing system according to an embodiment of the present disclosure is an information processing system including:
a vehicle; and
an information processing apparatus configured to calculate a service life of a battery that drives the vehicle,
wherein
the information processing apparatus is configured to request the vehicle to provide travel data,
when a first user who has sold the vehicle has agreed to provide the travel data to a second user who has purchased the vehicle, the vehicle is configured to provide the information processing apparatus with a first elapsed time, a first degradation level, and a first actual number of charges of the battery that are calculated based on data measured by a battery sensor,
when the first elapsed time, the first degradation level, and the first actual number of charges are provided from the vehicle, the information processing apparatus is configured to:
   calculate a first service life of the battery by multiplying a number of years obtained by subtracting the first elapsed time from a guaranteed service life of the battery by the first degradation level; and
   calculate a first remaining number of charges of the battery by subtracting the first actual number of charges from a guaranteed number of charges of the battery,
when the first user does not agree to provide the travel data to the second user, the vehicle is configured to notify the information processing apparatus that the travel data is not provided, and
when the first elapsed time, the first degradation level, and the first actual number of charges are not provided from the vehicle, the information processing apparatus is configured to:
   estimate a second elapsed time of the battery from a total travel distance and a manufacturing date of the vehicle;
   estimate a second degradation level and a second actual number of charges of the battery by applying the second elapsed time to predetermined statistical information;
   calculate an estimate of a second service life of the battery from the second elapsed time and the second degradation level; and
   calculate an estimate of a second remaining number of charges of the battery from the second actual number of charges.

An information processing apparatus according to an embodiment of the present disclosure is an information processing apparatus configured to calculate a service life of a battery that drives a vehicle, the information processing apparatus including:
a controller configured to, when a first elapsed time, a first degradation level, and a first actual number of charges of the battery are provided from the vehicle, calculate a first service life of the battery from the first elapsed time and the first degradation level, and calculate a first remaining number of charges of the battery from the first actual number of charges,
wherein when the first elapsed time, the first degradation level, and the first actual number of charges are not provided from the vehicle, the controller is configured to estimate a second elapsed time of the battery from a total travel distance and a manufacturing date of the vehicle, estimate a second degradation level and a second actual number of charges of the battery by applying the second elapsed time to predetermined statistical information, calculate an estimate of a second service life of the battery from the second elapsed time and the second degradation level, and calculate an estimate of a second remaining number of charges of the battery from the second actual number of charges.

A non-transitory computer readable medium according to an embodiment of the present disclosure stores a program configured to cause an information processing apparatus configured to calculate a service life of a battery that drives a vehicle to execute operations, the operations including:
when a first elapsed time, a first degradation level, and a first actual number of charges of the battery are provided from the vehicle, calculating a first service life of the battery from the first elapsed time and the first degradation level, and calculating a first remaining number of charges of the battery from the first actual number of charges; and
when the first elapsed time, the first degradation level, and the first actual number of charges are not provided from the vehicle, estimating a second elapsed time of the battery from a total travel distance and a manufacturing date of the vehicle, estimating a second degradation level and a second actual number of charges of the battery by applying the second elapsed time to predetermined statistical information, calculating an estimate of a second service life of the battery from the second elapsed time and the second degradation level, and calculating an estimate of a second remaining number of charges of the battery from the second actual number of charges.

According to an embodiment of the present disclosure, technology related to estimating the degradation levels of batteries that drive vehicles is improved.

### BRIEF DESCRIPTION OF THE DRAWINGS

In the accompanying drawings:

FIG. 1 is a block diagram illustrating an example of a schematic configuration of an information processing system according to an embodiment of the present disclosure;

FIG. 2 is a flowchart illustrating an example of operations of the information processing system; and

FIG. 3 is a diagram illustrating an example of predetermined statistical information.

### DETAILED DESCRIPTION

### Outline of Embodiment

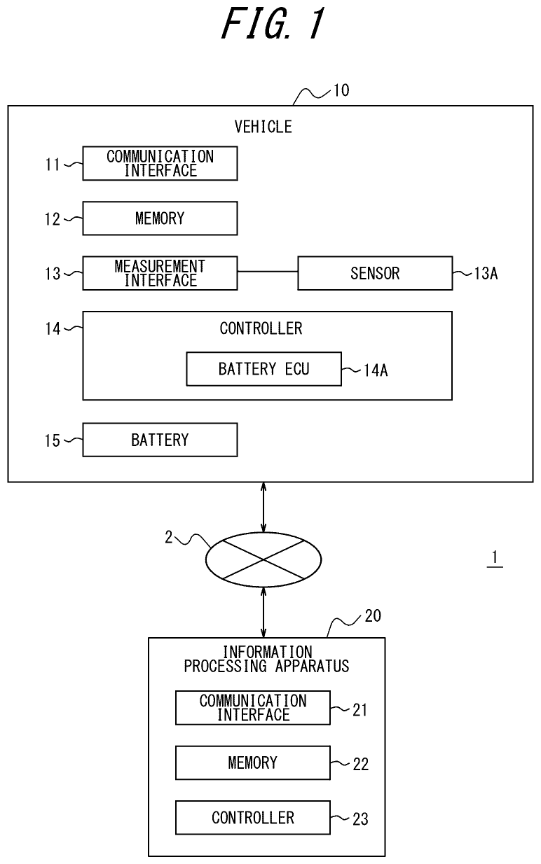

With reference to FIG. 1, an overview of the information processing system 1 according to the embodiment of the present disclosure will be described. The information processing system 1 includes a vehicle 10 and an information processing apparatus 20 that calculates the durability of the battery 15 that drives the vehicle 10. The vehicle 10 and the information processing apparatus 20 are communicably connected to a network 2 including, for example, the Internet and a mobile communication network.

The vehicle 10 is an electric vehicle (electric vehicle) equipped with a drive battery (hereinafter simply referred to as battery). The electric vehicle may be a Battery Electric Vehicle (BEV) or a Plug-in Hybrid Electric Vehicle (PHEV), but is not limited to these.

The information processing apparatus 20 is, for example, a computer such as a server apparatus. The information processing apparatus 20 can communicate with the vehicle 10 via the network 2.

### Configuration of Vehicle

As illustrated in FIG. 1, the vehicle 10 includes a communication interface 11, a memory 12, a measurement interface 13, a controller 14, and a battery 15.

The communication interface 11 includes a communication interface for wireless connection to the network 2. The communication interface connected to the network 2 corresponds to, for example, mobile communication standards. In the present embodiment, the vehicle 10 communicates with the information processing apparatus 20 via the network 2.

The memory 12 includes one or more memories. The memories are, for example, semiconductor memories, magnetic memories, optical memories, or the like, but are not limited to these. The memory 12 stores any information to be used for the operations of the vehicle 10. For example, the memory 12 may store a system program, an application program, and the like.

The measurement interface 13 includes a sensor 13A. The sensor 13A is a battery sensor that continuously measures data such as temperature changes, voltage fluctuations, and charge/discharge cycles of the battery 15 that drives the vehicle 10, which will be described later. However, the sensor 13A is not limited to these.

The controller 14 includes at least one processor, at least one programmable circuit, at least one dedicated circuit, or a combination of these. The processor is, for example, a general purpose processor such as a central processing unit (CPU) or a graphics processing unit (GPU), or a dedicated processor that is dedicated to specific processing, but is not limited to these. The programmable circuit is a field-programmable gate array (FPGA), for example, but is not limited to this. The dedicated circuit is an application specific integrated circuit (ASIC), for example, but is not limited to this. The controller 14 controls operations of the entire vehicle 10.

As illustrated in FIG. 1, in the present embodiment, the controller 14 functions as a battery ECU (Electronic Control Unit) 14A. The battery ECU 14A cooperates with the sensor 13A to control the charge and discharge cycles of the battery 15, and calculates and manages indicators such as the state of charge, elapsed time, degradation level, and actual charge count of the battery 15.

The battery 15 is a drive battery that serves as a power source for the vehicle 10 to travel. The battery 15 may be, for example, a nickel-hydride battery, a lithium-ion battery, or a solid-state battery, but is not limited to these.

### Configuration of Information Processing Apparatus

As illustrated in FIG. 1, the information processing apparatus 20 includes a communication interface 21, a memory 22, and a controller 23.

The communication interface 21 includes at least one interface for communication for connecting to the network 2. The communication interface connected to the network 2 corresponds to, for example, mobile communication standards or wireless LAN (Local Area Network) standards. In the present embodiment, the information processing apparatus 20 communicates with the vehicle 10 via the network 2.

The memory 22 includes one or more memories. The memories are, for example, semiconductor memories, magnetic memories, optical memories, or the like, but are not limited to these. The memory 22 stores any information to be used for operations of the information processing apparatus 20. The memory 22 may store a system program, an application program, and predetermined statistical information, or the like.

The controller 23 includes at least one processor, at least one programmable circuit, at least one dedicated circuit, or a combination of these. The controller 23 controls operations of the entire information processing apparatus 20.

### Flow of Operations of Information Processing Apparatus

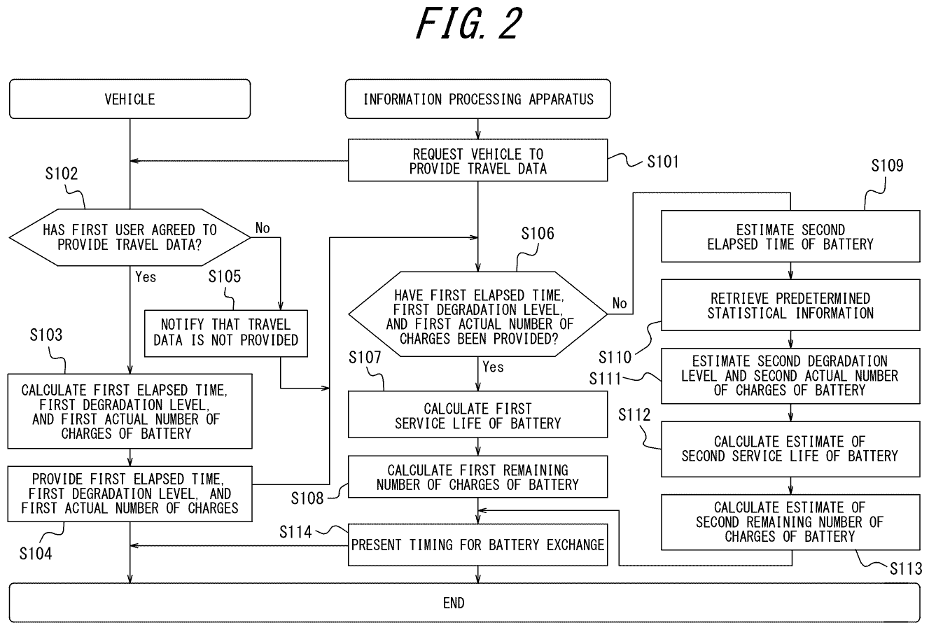

With reference to FIG. 2, operations of the information processing system 1 and the information processing apparatus 20 according to the present embodiment will be described.
S101: The controller 23 of the information processing apparatus 20 requests the vehicle 10 to provide travel data.

The travel data is data that measures the state of the vehicle 10 and the battery 15 that drives the vehicle 10, including the travel record of the vehicle 10, the elapsed time, degradation level, and actual number of charges of the battery 15. The total travel distance and manufacturing date of the vehicle 10 are publicly accessible data and are not included in the travel data. The elapsed time is the number of years that have passed since the manufacturing date of the vehicle 10. The degradation level refers to the ratio of the usable electrical energy Wp to the battery capacity W (Wp/W) of the battery 15. The usable electrical energy Wp is the amount of electrical energy (kwh) that can actually be extracted from the battery 15. The actual number of charges is the number of times the battery 15 has been charged as a “new” battery.
S102: The controller 14 of the vehicle 10 checks whether the first user who sold the vehicle 10 has agreed to provide the travel data to the second user who purchased the vehicle 10. If the first user agrees to provide the travel data, proceed to S103; if not, proceed to S105.

Since the travel data includes personal information such as the travel record of the vehicle 10 by the first user and the driving patterns of the vehicle 10, the consent of the first user is required for the transfer to the second user.
S103: The controller 14 (Battery ECU 14A) calculates the first elapsed time, first degradation level, and first actual number of charges of the battery 15.

Sensor 13A is a battery sensor that continuously measures data such as temperature changes, voltage fluctuations, and charge/discharge cycles of the battery 15. The Battery ECU 14A calculates the first elapsed time, first degradation level, and first actual number of charges of the battery 15 based on the data measured by the sensor 13A. The “first” attached to the first elapsed time, first degradation level, and first actual number of charges, as well as the first service life and first remaining charge count mentioned later, means that the data was calculated by the Battery ECU 14A.
S104: The controller 14 provides the first elapsed time, first degradation level, and first actual number of charges of the battery 15 to the information processing apparatus 20.
S105: The controller 14 notifies the information processing apparatus 20 that it will not provide the travel data.
S106: The controller 23 checks whether the first elapsed time, first degradation level, and first actual number of charges have been provided from the vehicle 10. If the data is provided from vehicle 10, proceed to S107; if the data is not provided, proceed to S109.
S107: The controller 23 calculates the first service life of battery 15 from the first elapsed time and the first degradation level.

The controller 23 calculates the first service life of the battery by subtracting the first elapsed time (elapsed time) from the warranty period of battery 15 and multiplying the result by the first degradation level (degradation level) as shown in the following formula (1). The warranty period is the warranty period of battery 15 provided by the manufacturer of vehicle 10. For example, if the warranty period is 8 years, the first elapsed time (elapsed time) is 4 years, and the first degradation level (degradation level) is 0.75(75 %), the first service life (service life) is calculated to be 3 years.

$$Service life = ( Warranty period - Elapsed time ) \times Degradation level \qquad ( 1 )$$

S108: The controller 23 calculates the first remaining charge count of battery 15 from the first actual number of charges.

The controller 23 calculates the remaining charge count of battery 15 by subtracting the first actual number of charges (actual number of charges) from the warranty charge count of battery 15 as shown in the following formula (2).

$$Remaining charge count = Warranty charge count - Actual number of charges \qquad ( 2 )$$

S109: The controller 23 estimates the second elapsed time of battery 15 from the total driving distance of vehicle 10 and the manufacturing date.

Hereinafter, the “second” in the second elapsed time, second degradation level, second actual number of charges, second service life, and second remaining charge count means estimated data (estimates) estimated by the controller 23, not calculated data by battery ECU 14A. For example, if the manufacturing date of vehicle 10 is Jan. 15, 2021, and the current date is Jan. 22, 2025, the controller 23 estimates the second elapsed time to be 4 years.
S110: The controller 23 searches for statistical information applicable to the model of vehicle 10 from the predetermined statistical information stored in memory 22.

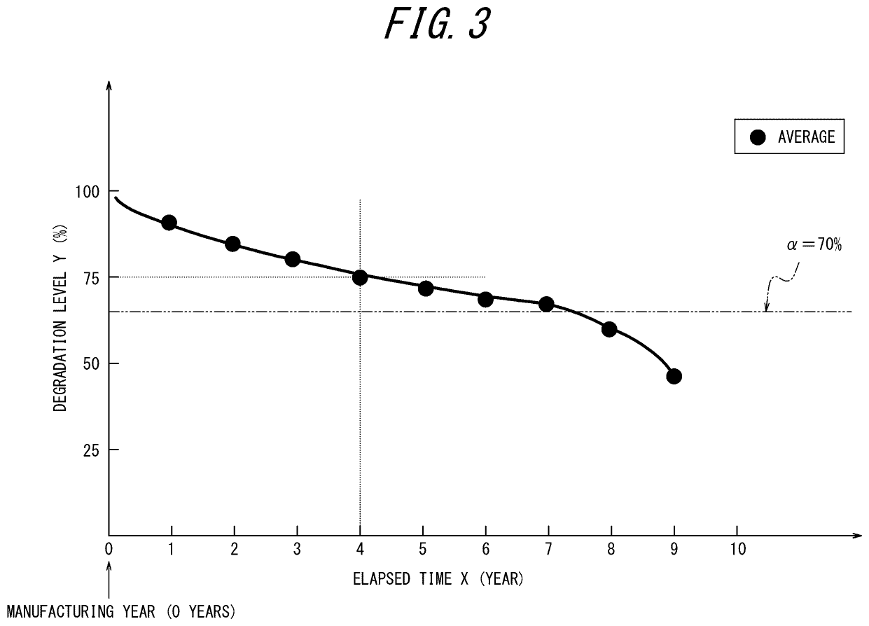

The predetermined statistical information in this embodiment is information in which respective degradation levels and actual numbers of charges of batteries aggregated from multiple vehicles classified according to vehicle model are statistically processed against elapsed times from manufacturing dates of the vehicles. However, the statistical information included in the predetermined statistical information is not limited to the degradation levels and actual numbers of charges of batteries. FIG. 3 is a diagram illustrating an example of predetermined statistical information. FIG. 3 is statistical data of the average degradation level Y of the battery against the elapsed time X from the manufacturing date for multiple vehicles of the same model as vehicle 10. However, the statistical data of the battery degradation level Y against the elapsed time X is not limited to the average value and may also be data of average ±2σ (σ is the standard deviation). Although not shown in FIG. 3, the predetermined statistical information includes statistical data of the average actual number of charges Z of the battery against the elapsed time X.
S111: The controller 23 estimates the second degradation level and the second actual number of charges of battery 15 by applying the second elapsed time to the predetermined statistical information.

When the second elapsed time from the manufacturing date of the vehicle 10 is 4 years, the controller 23 estimates that the second degradation level (degradation level Y) of the battery 15 is 0.75(75 %) by applying 4 years to the elapsed time X of the statistical information shown in FIG. 3. The controller 23 also estimates the second actual number of charges (actual number of charges Z) of the battery 15 by applying 4 years to the elapsed time X of a different statistical information than FIG. 3.
S112: The controller 23 calculates an estimate of the second service life of the battery 15 from the second elapsed time and the second degradation level.

Using the above formula (1), the controller 23 calculates an estimate of the second service life of the battery 15 by multiplying the number of years obtained by subtracting the second elapsed time from the warranty period of the battery 15 by the second degradation level. For example, if the warranty period is 8 years, the second elapsed time (elapsed time) is 4 years, and the second degradation level (degradation level) is 0.75(75 %), the first service life (service life) is calculated to be 3 years.

In this embodiment, the lifespan of the battery 15 is defined as when the degradation level falls below a threshold α (70%). As shown in FIG. 3, when the elapsed time X of the vehicle 10 is 4 years, the degradation level Y of the battery 15 is estimated to be 0.75(75 %). Furthermore, after the elapsed time X exceeds 7 years, the degradation level Y falls below the threshold α (70%). Therefore, the controller 23 may estimate the second service life from the statistical information in FIG. 3 to be 3 years.
S113: The controller 23 calculates an estimate of the second remaining number of charges of the battery 15 from the second actual number of charges.

Using the above formula (2), the controller 23 calculates an estimate of the second remaining number of charges of the battery 15 by subtracting the second actual number of charges from the warranty number of charges of the battery 15.
S114: The controller 23 determines the timing for battery replacement based on the first service life and the first remaining number of charges of the battery 15, or the second service life and the second remaining number of charges of the battery 15, and presents the timing for battery replacement to the vehicle 10.

If the service life is 3 years, the controller 23 presents to the second user of the vehicle 10 that battery replacement is advisable within 3 years. Additionally, the controller 23 may suggest future usage to the second user of the vehicle 10 based on the degradation level and the remaining number of charges. For example, if (i) the degradation level is 75% and the remaining number of charges is 1,000 times, the controller 23 determines that the battery 15 is degraded but has a margin in the number of charges, and may suggest maintaining the battery 15 by frequent rapid charging that does not exceed 80%. Also, if (ii) the degradation level is 85% and the remaining number of charges is 300 times, the controller 23 determines that the battery 15 is not degraded but has no margin in the number of charges, and may suggest maintaining the battery 15 by performing long hours of normal charging at night. Furthermore, if (iii) the degradation level is below the threshold α (70%), the controller 23 determines that the battery 15 has reached the end of its life and may suggest that battery replacement is immediately necessary.

As described above, the information processing apparatus 20 according to this embodiment calculates the first service life of the battery 15 from the first elapsed time, first degradation level, and first actual number of charges provided from the vehicle 10, and calculates the first remaining number of charges of the battery 15 from the first actual number of charges. When the first elapsed time, first degradation level, and first actual number of charges are not provided from the vehicle 10, it estimates the second elapsed time of the battery 15 from the total travel distance and manufacturing date of the vehicle 10, estimates the second degradation level and second actual number of charges of the battery 15 by applying the second elapsed time to predetermined statistical information, calculates an estimate of the second service life of the battery 15 from the second elapsed time and second degradation level, and calculates an estimate of the second remaining number of charges of the battery 15 from the second actual number of charges.

According to such a configuration, when the first elapsed time, first degradation level, and first actual number of charges of the battery 15 are not provided from the vehicle 10, the second service life and second remaining number of charges of the battery 15 are estimated based on the total travel distance and manufacturing date of the vehicle 10 and predetermined statistical information. Therefore, even if the first user who sold the vehicle 10 does not agree to transfer the travel data, the second user who purchased the vehicle 10 can obtain estimates of the service life and remaining number of charges of the battery 15, and can understand the timing for battery replacement. According to an embodiment of the present disclosure, technology related to estimating the degradation levels of batteries that drive vehicles is improved.

While the present disclosure has been described with reference to the drawings and examples, it should be noted that various modifications and revisions may be implemented by those skilled in the art based on the present disclosure. Accordingly, such modifications and revisions are included within the scope of the present disclosure. For example, functions or the like contained in each component, each step, or the like can be rearranged without logical inconsistency, and a plurality of components, steps, or the like can be combined into one or divided.

For example, an embodiment in which the configuration and operations of the information processing apparatus 20 in the above embodiment are distributed to multiple computers capable of communicating with each other can be implemented. For example, a server apparatus connected communicably to network 2 may manage predetermined statistical information and provide that statistical information to information processing apparatus 20 via network 2.

For example, an embodiment in which a general purpose computer functions as the information processing apparatus 20 according to the above embodiment can also be implemented. Specifically, a program in which processes for realizing the functions of the information processing apparatus 20 according to the above embodiment are written may be stored in a memory of a general purpose computer, and the program may be read and executed by a processor. Accordingly, the present disclosure can also be implemented as a program executable by a processor, or a non-transitory computer readable medium storing the program.

1. An information processing system comprising:
a vehicle; and
an information processing apparatus configured to calculate a service life of a battery that drives the vehicle,
wherein
the information processing apparatus is configured to request the vehicle to provide travel data,
when a first user who has sold the vehicle has agreed to provide the travel data to a second user who has purchased the vehicle, the vehicle is configured to provide the information processing apparatus with a first elapsed time, a first degradation level, and a first actual number of charges of the battery that are calculated based on data measured by a battery sensor,
when the first elapsed time, the first degradation level, and the first actual number of charges are provided from the vehicle, the information processing apparatus is configured to:
calculate a first service life of the battery by multiplying a number of years obtained by subtracting the first elapsed time from a guaranteed service life of the battery by the first degradation level; and
calculate a first remaining number of charges of the battery by subtracting the first actual number of charges from a guaranteed number of charges of the battery,
when the first user does not agree to provide the travel data to the second user, the vehicle is configured to notify the information processing apparatus that the travel data is not provided, and
when the first elapsed time, the first degradation level, and the first actual number of charges are not provided from the vehicle, the information processing apparatus is configured to:
estimate a second elapsed time of the battery from a total travel distance and a manufacturing date of the vehicle;
estimate a second degradation level and a second actual number of charges of the battery by applying the second elapsed time to predetermined statistical information;
calculate an estimate of a second service life of the battery from the second elapsed time and the second degradation level; and
calculate an estimate of a second remaining number of charges of the battery from the second actual number of charges.

2. An information processing apparatus configured to calculate a service life of a battery that drives a vehicle, the information processing apparatus comprising:
a controller configured to, when a first elapsed time, a first degradation level, and a first actual number of charges of the battery are provided from the vehicle, calculate a first service life of the battery from the first elapsed time and the first degradation level, and calculate a first remaining number of charges of the battery from the first actual number of charges,
wherein when the first elapsed time, the first degradation level, and the first actual number of charges are not provided from the vehicle, the controller is configured to estimate a second elapsed time of the battery from a total travel distance and a manufacturing date of the vehicle, estimate a second degradation level and a second actual number of charges of the battery by applying the second elapsed time to predetermined statistical information, calculate an estimate of a second service life of the battery from the second elapsed time and the second degradation level, and calculate an estimate of a second remaining number of charges of the battery from the second actual number of charges.

3. The information processing apparatus according to claim 2, wherein the controller is configured to calculate the first service life of the battery by multiplying a number of years obtained by subtracting the first elapsed time from a guaranteed service life of the battery by the first degradation level, and calculate the first remaining number of charges of the battery by subtracting the first actual number of charges from a guaranteed number of charges of the battery.

4. The information processing apparatus according to claim 2, wherein the controller is configured to calculate an estimate of a second service life of the battery by multiplying a number of years obtained by subtracting the second elapsed time from a guaranteed service life of the battery by the second degradation level, and calculate the estimate of the second remaining number of charges of the battery by subtracting the second actual number of charges from a guaranteed number of charges of the battery.

5. The information processing apparatus according to claim 2, wherein the predetermined statistical information is information in which respective degradation levels and actual numbers of charges of batteries aggregated from multiple vehicles classified according to vehicle model are statistically processed against elapsed times from manufacturing dates of the vehicles.

6. A non-transitory computer readable medium storing a program configured to cause an information processing apparatus configured to calculate a service life of a battery that drives a vehicle to execute operations, the operations comprising:
when a first elapsed time, a first degradation level, and a first actual number of charges of the battery are provided from the vehicle, calculating a first service life of the battery from the first elapsed time and the first degradation level, and calculating a first remaining number of charges of the battery from the first actual number of charges; and
when the first elapsed time, the first degradation level, and the first actual number of charges are not provided from the vehicle, estimating a second elapsed time of the battery from a total travel distance and a manufacturing date of the vehicle, estimating a second degradation level and a second actual number of charges of the battery by applying the second elapsed time to predetermined statistical information, calculating an estimate of a second service life of the battery from the second elapsed time and the second degradation level, and calculating an estimate of a second remaining number of charges of the battery from the second actual number of charges.
